(19) United States
(12) Patent Application Publication
(10) Pub. No.: US 2014/0369005 A1
(43) Pub. Date: Dec. 18, 2014

(54) PASSIVE THERMAL MANAGEMENT DEVICE

(71) Applicant: Commissariat a l'energie atomique et aux ene alt, Paris (FR)

(72) Inventors: Jerome Gavillet, Saint-Egreve (FR); Jean Dijon, Champagnier (FR)

(73) Assignee: Commissariat a l'energie atomique et aux ene alt, Paris (FR)

(21) Appl. No.: 14/371,300

(22) PCT Filed: Jan. 8, 2013
(86) PCT No.: PCT/EP13/50217

§ 371 Date: Jul. 9, 2014

(30) Foreign Application Priority Data
Jan. 10, 2012 (FR) 1250240

(51) Int. Cl. H05K 7/20; C23C 16/02; C23C 16/26; F28D 15/02; B21D 53/02

(52) U.S. Cl. CPC H05K 7/2029; F28D 15/02; B21D 53/02; C23C 16/26; C23C 16/0236; C23C 16/0272; B82Y 99/00
USPC 361/699; 165/104.21; 29/890.032; 427/249.3; 216/39; 977/742

(57) ABSTRACT

A thermal management device including a first face configured to be in contact with a hot source and a second face opposite the first face configured to be in contact with a cold source, and at least one network of cells filled with a solid/liquid phase-change material located in a cavity between the first and second faces, wherein the cells include walls formed of carbon nanotubes, wherein the nanotubes extend roughly from the first to the second face, thermally connecting the first face to the second face.

### TECHNICAL FIELD AND PRIOR ART

The present invention relates to a passive thermal management device, which can be used for example to cool electronic components.

An increasing number of functions are confined in electronic systems. At the same time, it is sought to reduce the size of these components. This tendency leads to an increasing heat dissipation per unit of volume (or of mass) of component.

Traditional cooling means, such as air convection, whether natural or forced, are not sufficient to evacuate this heat.

In addition to the greater quantity of heat to be evacuated, the problem of evacuation heat in transient mode is also posed, when the heat flux is relatively high and the load duration is relatively short.

It has been envisaged to integrate micro-channels within the components, associated with an external, active heat transfer fluid circulation system. This technique is relatively efficient at extracting the heat whilst limiting thermal resistance at the contacts. The external, active system is, for example, formed by a micropump. This technique results in quite bulky products; in addition, problems of reliability may be posed over time, and maintenance is required.

The use of refrigerating fluids has the advantage of using a latent vaporisation heat during a change of phase, in addition to a very efficient convective cooling. This leads to greater thermal power dissipation, whilst maintaining the surface temperature relatively low and uniform. For example, for a chip junction at 85° C., pool boiling of a heat transfer fluid of the fluorocarbon FC72 type enables heat fluxes of the order of 50 W/cm² to be dissipated, whilst an air-cooled radiator can dissipate only a power rating of 0.1 W/cm², for equivalent dimensions. However, heat dissipation by change of phase remains limited for high thermal loads. Indeed, the maximum dissipation threshold by boiling or evaporation depends on the thermo-physical properties of the heat transfer fluid, on the hydrodynamic two-phase flow regime, and on the surface energy conditions, and remains limited by the critical heat flux, which leads to an irreversible drying of the surface and to a spontaneous fall of the heat transfer through this surface.

Document US 2006/0231970 describes a thermal interface material intended to be positioned between a heat source and a heat dissipation device. The material comprises carbon nanotubes immersed in a matrix made of a phase-change material, such as paraffin. The carbon nanotubes extend in discrete fashion and longitudinally between the heat source and the heat dissipation device. The ends of the nanotubes protrude from the surfaces of the thermal interface material, and are in contact with the heat source and the thermal dissipation device, forming a thermal conduction path between the heat source and the heat dissipation device. The thermal transfer between the source and the thermal dissipation device occurs principally via the nanotubes. When the phase-change material changes from solid state to liquid state under the effect of the heat emitted by the source, this material fills the space between the heat source and the thermal dissipation device, and provides a thermal interface between the heat source and the thermal dissipation device.

The thermal interface material is around one micrometre thick, to provide a certain flexibility. This material allows efficient evacuation of the heat in a nominal regime, i.e. when the heat flux is relatively low and the load duration is relatively long. However, in a transient regime, when the heat flux is relatively high and the load duration is relatively short, this material no longer allows efficient thermal management.

### DESCRIPTION OF THE INVENTION

One aim of the present invention is consequently to provide an efficient passive thermal management device to evacuate the heat both in a nominal regime and in a transient regime.

The aim of the present invention is attained by a thermal management device comprising cells containing a solid/liquid phase-change material, where the walls of the cells are formed by carbon nanotubes, and where the nanotubes form a thermal short-circuit between the heat source and the thermal dissipator.

Due to their very satisfactory thermal conductivity, the nanotubes evacuate the heat in the nominal regime by conduction. In a transient regime the phase-change material, by changing from the solid state to the liquid state, temporarily absorbs the heat. The cells are preferably relatively small in size, such that the nanotube walls of the cells enable the heat to be distributed in a controlled and predefined manner within the phase-change material.

In the nominal regime the heat is therefore evacuated principally by conduction by means of the nanotubes, and in a transient regime the heat is principally stored by a change of phase, and then evacuated by conduction by means of the nanotubes.

In a very advantageous manner the nanotubes are in contact with one another such that the walls of the cells are made of a dense material, providing improved thermal conductivity in the lateral direction, and a greater available volume for the phase-change material.

One subject-matter of the present invention is then a thermal management device comprising a first face intended to be in contact with a hot source (SC) and a second face opposite the first face intended to be in contact with a cold source, at least one network of cells filled with a solid/liquid phase-change material positioned between the first and second faces, the cells comprising walls formed of carbon nanotubes, said nanotubes extending roughly from the first to the second face, thermally connecting the first face to the second face.

The walls of the cells preferably form a continuous lateral partition.

Very advantageously, the walls of the cells are formed of nanotubes in contact so as to form a dense material.

The transverse dimension of each cell is preferably less than or equal to the melt front distance, where the melt front distance is of the order of

$$\sqrt{\frac{2 \cdot k \cdot Δ T \cdot t}{L}} ,$$

where k is the thermal conduction of the phase-change material, L is the latent heat of fusion the phase-change material, ΔT is the temperature difference between the temperature of the wall of a cell during a thermal overload and the phase-change temperature of the phase-change material, and t is the time.

In one embodiment the device comprises a support having at least one cavity and a cover sealing said cavity, where said cavity comprises a network of cells made of carbon nanotubes filled with phase-change material.

A ductile thermal conductor material can advantageously be interposed between the cover and the network of cells, or between the bottom of the cavity and the network of cells.

In one example embodiment the network of cells is fixed to the cover.

In another example embodiment the network of cells is fixed to the bottom of the cavity.

The thermal management device according to the invention can comprise several cavities.

For example, the area of the cavity or cavities is between 1000 μm² and 10 cm².

The support can be between 0.5 mm and 1 mm thick, and is preferably 750 μm thick, and cavity or cavities 16 can be between 50 μm and 500 μm deep.

Another subject-matter of the present invention is an electronic system comprising at least one electronic component forming a heat source, at least one heat evacuation device forming a cold source and at least one thermal management device according to the invention, the electronic component being in thermal contact with the first face of the thermal management device and the heat evacuation device is in thermal contact with the second face.

Another subject-matter of the present invention is a method for the manufacture of a thermal management device according to the invention, comprising the following steps:

a) definition of the pattern of the network of cells on a substrate by deposition of resin and lithography of it,

b) deposition of a catalyst layer,

c) removal of the resin,

d) growth of the carbon nanotubes, by chemical vapour deposition,

e) filling of the cells with the phase-change material.

The catalyst may be iron or an aluminium and iron bilayer system.

The manufacturing method advantageously comprises a step of compacting of carbon nanotubes by immersing the network of cells in an alcohol solution, and drying it in air.

The manufacturing method can comprise, prior to steps a) to d), the steps of production of one or more cavities in a support, said cavity or cavities receiving a network of cells, and after step d) of closure of the cavity or cavities by a cover.

The substrate can be formed by the bottom of the cavity or cavities, and steps a) to d) can then take place on the bottom of the cavity or cavities.

The manufacturing method can advantageously comprise a step of deposition of a layer of ductile thermal conductive material on the bottom of the cavity or cavities intended to be pointing towards the interior of the cavity.

The substrate can be formed by the cover and steps a) to d) can then be accomplished on the cover. The manufacturing method can advantageously comprise a step of deposition of a layer of ductile thermal conductive material on a cover face intended to be pointing towards the interior of the cavity.

### BRIEF DESCRIPTION OF THE ILLUSTRATIONS

The present invention will be better understood using the description which follows and the appended illustrations, in which:

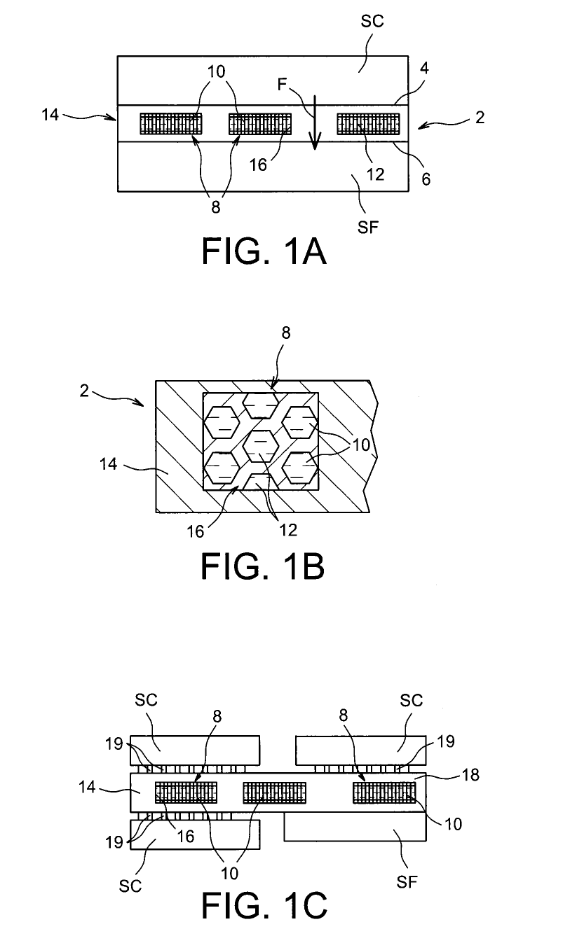

FIGS. 1A and 1B are longitudinal section and cross-section views, respectively, of a schematic representation of an example embodiment of a thermal management device according to the invention,

FIG. 1C is a longitudinal section view of another example of a thermal management device in contact with several hot sources,

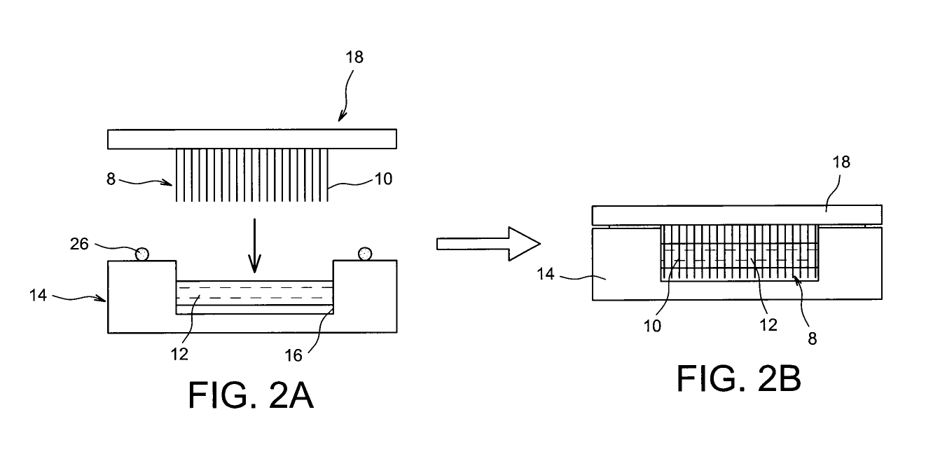

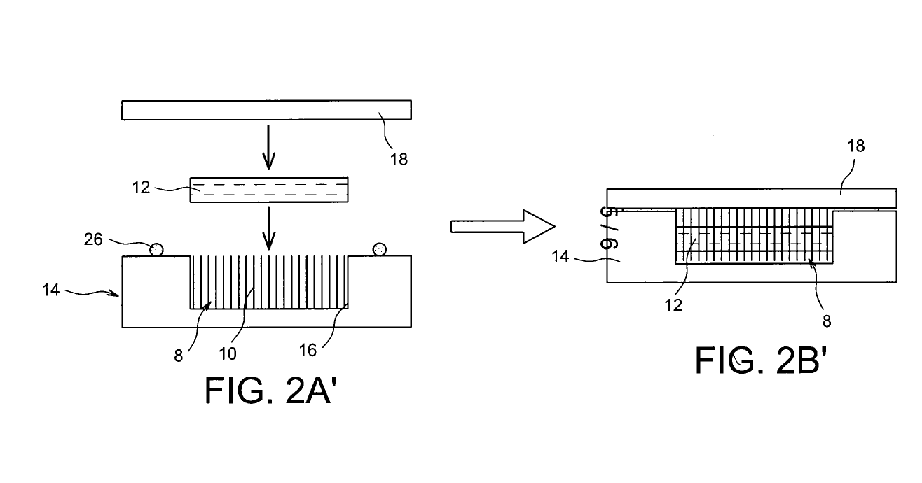

FIGS. 2A and 2B are schematic representations of an example of steps of production of the device according to the invention,

FIGS. 2A′ and 2B′ are schematic representations of another example of steps of production of the device according to the invention,

steps 3A to 3E are schematic representations of steps of production of the network of carbon nanotube cells,

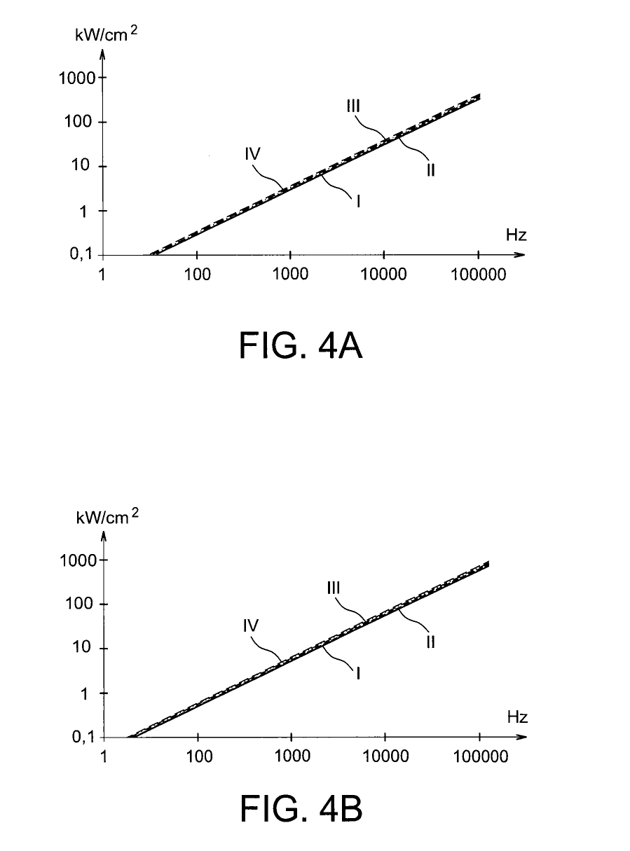

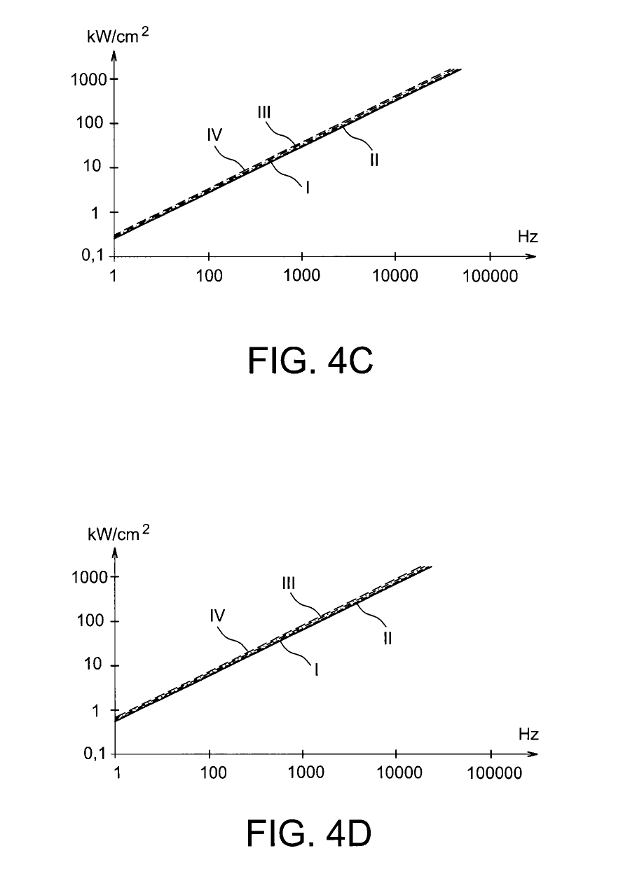

FIGS. 4A to 4D are graphical representations of the power flux density which can be stored according to the frequency of the thermal loads for four different phase-change materials, where the phase-change material thickness is different for each graphical representation,

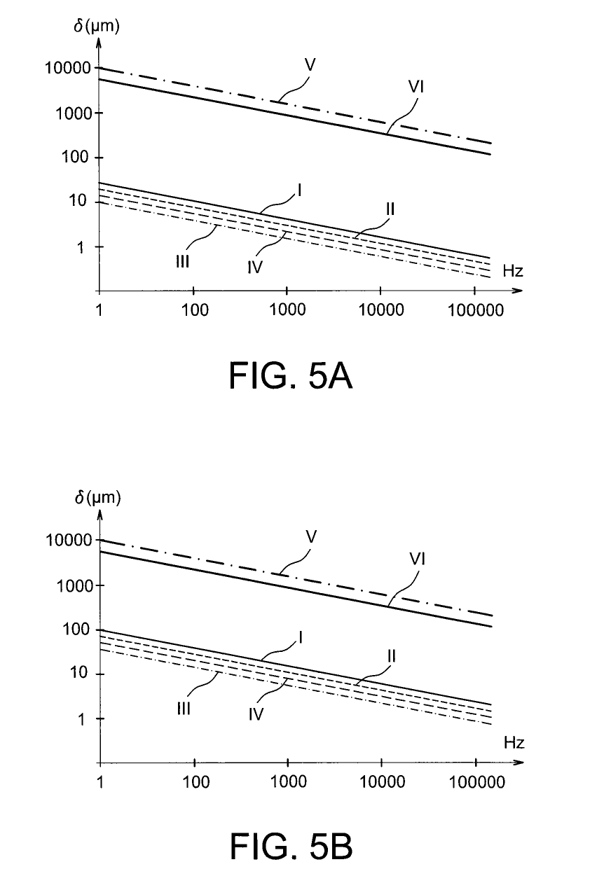

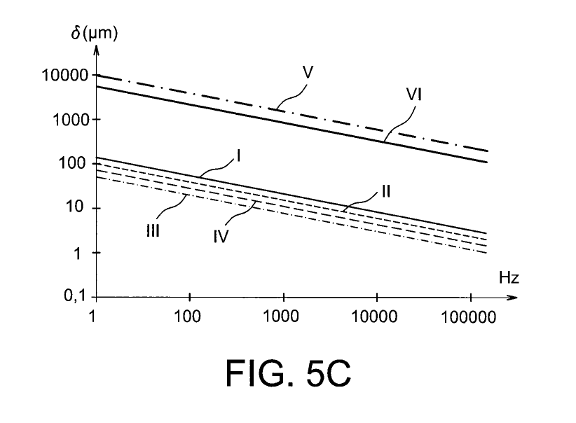

FIGS. 5A to 5C are graphical representations of the average thermal penetration depth according to the frequency of the thermal loads in four different phase-change materials, in copper and in the carbon nanotubes.

### DETAILED DESCRIPTION OF PARTICULAR EMBODIMENTS

In FIGS. 1A and 1B an example embodiment of a thermal management device 2 is seen represented schematically, positioned a hot source SC and a cold source SF.

For example, hot source SC is an electronic system and cold source SF is a radiator with fins.

The roughly flat-shaped device comprises a first face 4 intended to be in contact with hot source SC, and a second face 6 opposite first face 4 and intended to be in contact with the cold source.

The device comprises a thermal conductive support 14, for example made of monocrystalline silicon, in which multiple cavities 16 are produced, emerging in one of the faces of support 14. Each of cavities 16 contains a network of cells 8 made of carbon nanotubes and a phase-change material. Each cavity 16 is closed by a cover 18. First face 4 is formed by cover 18 and second face 6 by the bottom of support 14.

The device also comprises, positioned between its two faces 4, 6, several networks of cells 8 housed in cavities 16. The cells are delimited by closed side walls 10. Walls 10 extend roughly in the direction of heat flux F represented schematically by an arrow. The device also comprises a phase-change material 12 positioned in the cells. Walls 10 are made of carbon nanotubes, which have a very high thermal conductivity coefficient, for example of between 6 W·cm−1·K⁻¹ and 20 W·cm−1·K⁻¹.

Each end of network of cells 8, in the direction of the carbon nanotubes, is in thermal contact with the bottom of cavity 16 and cover 18. The length of the nanotubes is, for example, close to the depth of cavities 16. In an advantageous example a thermal conductive material having a certain ductility, for example a metal such as titanium, copper, or gold, etc., is positioned between cover 18 and the carbon nanotubes so as to provide satisfactory thermal contact, whilst providing a certain tolerance in the production of the nanotubes.

As we shall see subsequently, the nanotubes can be produced directly on cover 18 by growth on one face of the cover, or in cavity 16, by growth on the bottom of the latter. Alternatively, it can be envisaged to produce an independent assembly formed of a network of cells made of carbon nanotubes and of solid phase-change material. This assembly can be handled and an assembly would be positioned in each of the cavities.

In a very advantageous manner, walls 10 are produced such that the nanotubes collapse and form a dense material in which the nanotubes are in contact by their lateral surfaces.

The thickness of the walls is then reduced, which increases the volume of the cells and therefore the available volume for the phase-change material. In addition, the thermal conductivity of the walls is also increased.

For example, the compaction ratio is between 2 and 10, depending on the initial density of the walls.

In FIG. 1B a cross-section detail of the device of FIG. 1A can be seen, and in particular a top view of a network of cells with a honeycomb structure. However, this form is not exclusive, and a network in the form of square or rectangular cells does not go beyond the scope of the present invention. The honeycomb structure has the advantage of providing thermal isotropy in the plane.

In the represented example the cells are all the same size; however there could be cells of different sizes and/or different shapes within the same passive thermal management device.

The section of the cells is preferably chosen such that in a transient regime the entire phase-change material is melted, which enables the size of the device and the quantity of phase-change material used to be optimised.

The phase-change material is chosen such that it changes from the solid state to the liquid state when there is a thermal overload of hot source SC. For example, in the case of an electronic component, its operating temperature, also called its nominal temperature, is of the order of 90° C.; the solid/liquid phase-change temperature of the phase-change material is then higher than 90° C. In the table below examples of phase-change materials suitable for such an application are given. The phase-change temperatures are shown in the second column.

| | | | Density | | Specific | | Thermal conductivity | Diffusivity |
|---|---|---|---|---|---|---|---|---|
| PCM | T (° C.) | J/g | (Kg/m³) | KJ/cm³ | heat (J/g · K) | ΔV (%) | (W/K · m) | (m²/s) |
| Erythriol | 118 | 340 | 1480 | 0.5 | 1.38 | 13.8% | 2.64 | 1.29E−06 |
| PlusICE | 180 | 301 | 1330 | 0.4 | 1.38 | 9.0% | 0.99 | 5.41E−07 |
| X180 | | | | | | | | |
| A164 | 164 | 306 | 1500 | 0.5 | 1.38 | 10.0% | 0.20 | 9.66E−08 |
| H110 | 110 | 243 | 2145 | 0.5 | 2.41 | 10.0% | 0.45 | 8.70E−08 |

In FIG. 1C another example embodiment of the thermal management device according to the invention can be seen. This device is intended to be in contact with several hot sources SC. In addition, TSV (Through-Silicon Via) interconnections 19 are produced between the hot sources, for example microelectronic devices of the electronic chip type, and the heat exchange device.

We shall now explain the operation of the heat exchange device of FIG. 1A. The operation of FIG. 1C is similar to that of FIG. 1A.

In the nominal regime: the load corresponds to normal operation of hot source SC. The heat flux is relatively low, for example less than 1 W/cm², and the load duration is relatively high, for example longer than 10 seconds. The heat is transmitted to the cold source SF by the walls of the network of cells 8 made of nanotubes by conduction. The temperature of the thermal management device is then lower than the phase-change temperature of the change material, which therefore remains in the solid state: thermal storage in the phase-change material is then not activated in the nominal regime.

In a transient regime: the load corresponds to abnormal operation of hot source SC. The heat flux is relatively high, for example greater than 1 W/cm², and the load duration is relatively short, for example less than 10 seconds. The heat flux leads to a local temperature rise, such that the change material changes to the liquid state: thermal storage is activated. The heat is transmitted to the phase-change material by the walls made of nanotubes surrounding the phase-change material.

At the end of the transient regime the change material 10 solidifies, transferring its latent heat to the system, which dissipates by conduction to the cold source; the temperature becomes simultaneously lower than the phase-change temperature, and the thermal management device is once again available for the next transient regime. Thermal storage is deactivated.

In the operational example described, the nominal regime and the transient regime occur at different instants; however it is possible to envisage them occurring simultaneously, for example if the device is in contact with several hot sources. The device according to the invention enables the nominal and/or transient thermal loads to be managed thermally and simultaneously.

In FIGS. 4A to 4D storable power flux density DS can be seen represented, in kW/cm2, by different phase-change materials for different thicknesses of phase-change material, as a function of the frequency of the thermal loads in Hz, which represents their storage capacity.

A nominal temperature of the component to be cooled of the order of 90° C. is considered.

The storable power flux density is the product of the storable energy surface density and the thermal overload frequency.

The storable energy surface density is the sum of the latent heat available over a thickness H of phase-change material and the sensible heat available for the same phase-change material over the following temperature interval: Tₘₐₓ−Tₙₒₘᵢₙₐₗ, where Tₘₐₓ is the maximum temperature reached by the component during a thermal overload.

For all the graphical representations of FIGS. 4A to 4D, Tₘₐₓ−Tₙₒₘᵢₙₐₗ=10° C.

For FIG. 4A, H=50 μm, for FIG. 4B, H=100 μm, for FIG. 4C, H=500 μm and for FIG. 4D, H=1 mm.

The materials considered are:

I: Erythriol, the melting point of which is 118° C.;

II: PlusICEX180®, manufactured by PCMprocess, the melting point of which is 180° C.;

III: A164®, manufactured by PCMprocess, the melting point of which is 164° C.:

IV: H110®, manufactured by PCMprocess, the melting point of which is 110° C.

The storable power flux density is the product of the storable energy surface density and the thermal overload frequency. The latter is presented in the curves below for a temperature interval Tₘₐₓ−T_{MCP} of 10° C. and various thicknesses of phase-change materials.

It is observed:
that a thickness of 50 μm of phase-change material can store approximately 0.3 kW/cm² at 100 Hz, 3 kW/cm² at 1 kHz, 30 kW/cm² at 10 kHz and 300 kW/cm² at 100 kHz;
that a thickness of 100 μm of phase-change material can store twice the storable power with a thickness of 50 μm;
that a thickness of 500 μm of phase-change material can store 10 times the storable power with a thickness of 50 μm;
that a thickness of 1000 μm of phase-change material can store 20 times the storable power with a thickness of 50 μm;

In FIGS. 5A to 5C the change of thermal penetration depth in μm is represented as a function of the thermal load frequency in a transient regime.

The thermal penetration depth is the depth up to which the phase-change material changes to the liquid state. If this depth is known the size of the cells can be optimised such that the quantity of phase-change material corresponds to the storage of the heat in the event of a thermal overload.

At the scale of the phase-change material contained in a cell, the heat is conducted within the phase-change material. The heat transfer kinetics within the phase-change material then depend on the temperature conditions on the walls of the cells and on the physical properties of the phase-change material

$$s ( t ) = \sqrt{2 \frac{λ Δ T}{L} t} \qquad ( I )$$

where s(t) is the position of the phase-change front (or thermal penetration depth) at instant t,

λ is the thermal conductivity of the phase-change material in W/k·m,

ΔT is the temperature difference between the walls of the cell and the untransformed phase-change material,

L is the latent phase-change heat of the phase-change material in J/m³.

At the scale of the storage device the heat is conducted along the walls made of carbon nanotubes. The transfer kinetics then depend on the incident heat flux, the architecture and the physical properties of the cell network. Statistically, an average thermal penetration depth can be defined as follows:

$$δ ( ω ) = \sqrt{\frac{2 \cdot D}{ω}} \qquad ( II )$$

where D is the thermal diffusivity of the material in m²/s and ω the frequency of the thermal signal.

In the graphical representations of FIGS. 5A to 5C the depths of penetration of the heat in phase-change materials I, II, III and IV, in the carbon nanotubes (curve V), and in copper (curve VI) can be seen as a reference.

For all the figures the nominal temperature is 90° C. For FIG. 5A, ΔT=1° C., for FIG. 5B, ΔT=10° C. and for FIG. 5C, ΔT=20° C.

By reading the curves of FIGS. 5A to 5C enables the size of the cells to be determined in order that the entire phase-change material is melted in the event of a thermal overload.

It is therefore observed that, for the entire phase-change material to be melted:
for a ΔT of 1° C. and depending on the phase-change material, the optimum cell size is between 3 μm and 10 μm for a thermal overload frequency of less than or equal to 100 Hz;
for a ΔT of 1° C. and depending on the phase-change material, the optimum cell size is between 1 and 3 μm in size for a thermal overload frequency of less than or equal to 1 kHz;
for a ΔT of 1° C. and depending on the phase-change material, the optimum cell size is between 0.3 and 1 μm for a thermal overload frequency of less than or equal to 10 kHz;
for a ΔT of 1° C. and depending on the phase-change material, the optimum cell size is between 0.1 and 0.3 μm for a thermal overload frequency of less than or equal to 100 kHz;
for a ΔT of 10° C. and depending on the phase-change material, the optimum cell size is between 10 and 30 μm for a thermal overload frequency of less than or equal to 100 Hz;
for a ΔT of 10° C. and depending on the phase-change material, the optimum cell size is between 3 and 10 μm for a thermal overload frequency of less than or equal to 1 kHz;
for a ΔT of 10° C. and depending on the phase-change material, the optimum cell size is between 1 and 3 μm for a thermal overload frequency of less than or equal to 10 kHz;
for a ΔT of 10° C. and depending on the phase-change material, the optimum cell size is between 0.3 and 1 μm for a thermal overload frequency of less than or equal to 100 kHz;
for a ΔT of 20° C. and depending on the phase-change material, the optimum cell size is between 15 and 45 μm for a thermal overload frequency of less than or equal to 100 Hz;
for a ΔT of 20° C. and depending on the phase-change material, the optimum cell size is between 3 and 10 μm for a thermal overload frequency of less than or equal to 1 kHz;
for a ΔT of 20° C. and depending on the phase-change material, the optimum cell size is between 1 and 3 μm for a thermal overload frequency of less than or equal to 10 kHz;
for a ΔT of 20° C. and depending on the phase-change material, the optimum cell size is between 0.3 and 1 μm for a thermal overload frequency of less than or equal to 100 kHz.

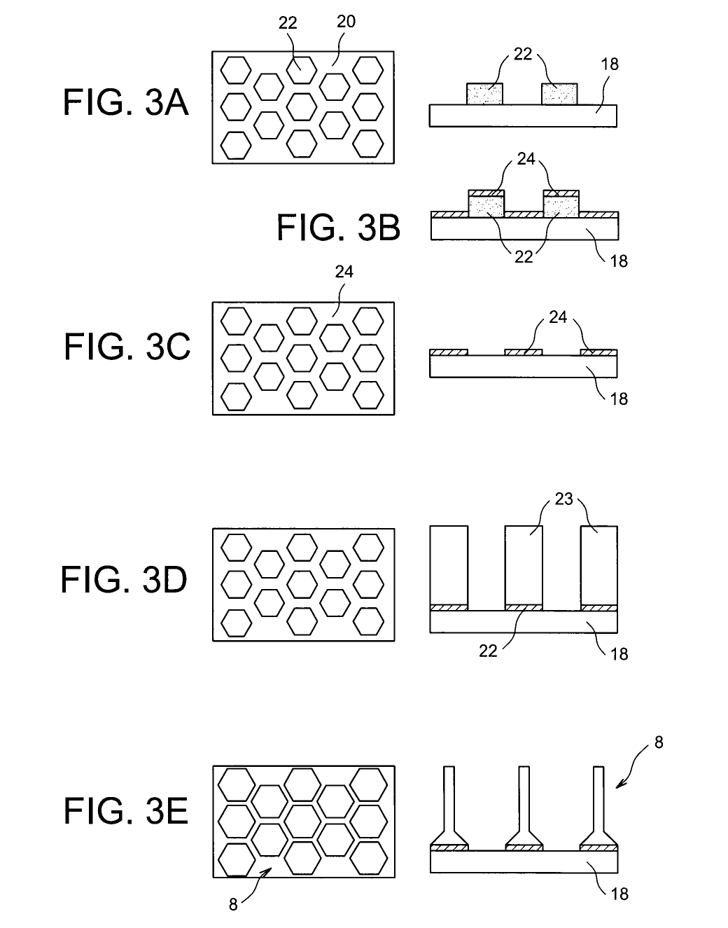

We shall now describe examples of methods of production of a thermal management device according to the invention, the steps of which are represented schematically in FIGS. 2A to 3D.

In FIGS. 2A and 2B a first example of a method of production can be seen in which the network of cells is produced on the cover.

In a first step cavity 16 is produced in a support 14 made of a thermal conductive material, for example monocrystalline silicon. Cavity 16 is produced, for example by water-based chemical etching, for example with KOH, or by deep dry etching, for example by Reactive-Ion Etching (RIE).

The thickness of the substrate is, for example, of the order of 0.5 mm to 1 mm. The depth of cavity 16 is of the order of 50 μm to 500 μm. The area of the cavities is typically between 1000 μm² and 100 cm².

A layer of ductile metal (not represented) is advantageously deposited at the bottom of cavity 16 to provide physical and thermal contact with the carbon nanotubes which will subsequently be positioned in the cavity. This layer can be deposited by physical vapour deposition, chemical vapour deposition, electroplating, etc.; it can be made of titanium, gold, copper, aluminium, etc.; it is typically between 10 nm and 10 μm thick.

This structure can be seen in FIG. 2A.

In a following step the network of cells is produced on the cover, as can be seen in FIG. 2A.

To this end a resin layer 22 is deposited on a face of cover 18, and a lithography of the pattern to be produced is made (FIG. 3A). In the represented case this is a honeycomb pattern.

In a following step (FIG. 3B), a catalyst 24 is deposited by physical vapour deposition. Catalyst 24 is, for example, a layer of iron, between 0.5 nm and 10 nm thick, preferably 1 nm thick, or a bilayer system comprising a 10 nm aluminium layer and a 1 nm iron layer.

In a following step resin 22 is removed (FIG. 3C).

In a following step nanotubes 23 are made to grow by thermal chemical vapour deposition with a blend of C₂H₂, H₂, He with gas flows of 10, 50, 50 cm³/min, for example, at a temperature of between 550° C. and 750° C. at a pressure of between 0.1 mbar and 10 mbar. The height of the tubes is determined by the growth time (FIG. 3D).

In an advantageous following step the tubes are compacted by immersion in an alcohol solution. During the air drying the nanotube walls collapse and form a dense material in which the nanotubes are in contact (FIG. 3E).

Cell network 8 is formed.

In a following step the cavities are filled with phase-change material 12.

Finally, cover 18 with cell network 8 is transferred to cavity 16, and the network penetrates into cavity 16. And cover 18 is sealed on to support 14. A seal 26 is made between the cover and the support.

In FIGS. 2A′ and 2B′, another example of a method of production can be seen in which cell network 10 is produced directly in cavity 16.

Firstly a cavity 16 is produced in a support 14, as described above.

Steps 3A to 3E are undertaken on the bottom of cavity 16. The height of the carbon nanotubes is close to the depth of cavity 16, roughly less than or greater than it.

Cavity 16 is then filled with a phase-change material 10.

A layer of metal (not represented) having a certain ductility is then preferably deposited locally on cover 18 to provide physical and thermal contact between the nanotubes and cover 18. This layer is produced as described above.

Finally, cover 18 is transferred on to support 14 to seal cavity 16. And cover 18 is sealed on to support 14. A seal 26 is made between cover 18 and support 14.

The device produced by the methods described above contains only one cavity, but it is clearly understood that the manufacturing steps described above apply to produce devices comprising several cavities as represented in FIGS. 1A and 1C.

The thermal management device is transferred on to an electronic component by microelectronic techniques well known to those skilled in the art.

The thermal management device according to the invention therefore enables transient or intermittent heat sources to be managed thermally, in particular in 3D electronic systems, for example to form a device integrated in electronic components using through vias, or TSVs.

1-20. (canceled)

21. A thermal management device comprising:
a first face configured to be in contact with a hot source;
a second face opposite the first face configured to be in contact with a cold source;
at least one network of cells filled with a solid/liquid phase-change material positioned between the first and second faces, the cells comprising walls formed of carbon nanotubes, said nanotubes extending roughly from the first to the second face, thermally connecting the first face to the second face, the walls of the cells being formed from nanotubes in contact to form a dense material.

22. The thermal management device according to claim 21, wherein the walls of the cells form a continuous lateral partition.

23. The thermal management device according to claim 21, wherein a transverse dimension of each cell is less than or equal to a melt front distance, wherein the melt front distance is of an order of
$$\sqrt{\frac{2 \cdot k \cdot Δ T \cdot t}{L}} ,$$
wherein k is thermal conduction of the phase-change material, L is latent heat of fusion the phase-change material, ΔT is a temperature difference between a temperature of the wall of a cell during a thermal overload and the phase-change temperature of the phase-change material, and t is time.

24. The thermal management device according to claim 21, further comprising a support with at least one cavity and a cover sealing said cavity, wherein said cavity comprises a network of cells made of carbon nanotubes filled with phase-change material.

25. The thermal management device according to claim 24, further comprising a ductile thermal conductive material interposed between the cover and the network of cells or between a bottom of the cavity and the network of cells.

26. The thermal management device according to claim 25, wherein the network of cells is fixed to the cover.

27. The thermal management device according to claim 24, wherein the network of cells is fixed to a bottom of the cavity.

28. The thermal management device according to claim 24, comprising plural cavities.

29. The thermal management device according to claim 24, wherein an area of the cavity or cavities is between 1000 μm² and 10 cm².

30. The thermal management device according to claim 24, wherein the support is between 0.5 mm and 1 mm thick and a depth of cavity or cavities is between 50 μm and 500 μm.

31. An electronic system comprising:
at least one electronic component forming a heat source;
at least one heat evacuation device forming a cold source; and
at least one thermal management device comprising a first face in contact with the at least one electronic component and a second face opposite the first face in contact with the at least one heat evacuation device, at least one network of cells filled with a solid/liquid phase-change material positioned between the first and second faces, the cells comprising walls formed of carbon nanotubes, said nanotubes extending roughly from the first to the second face, thermally connecting the first face to the second face, the walls of the cells being formed from nanotubes in contact to form a dense material.

32. A method for manufacturing a thermal management device according to claim 21, comprising:
a) definition of a pattern of the network of cells on a substrate by deposition of resin and lithography of the resin;
b) deposition of a catalyst layer;
c) removal of the resin;
d) growth of the carbon nanotubes, by chemical vapor deposition;
e) filling of the cells with the phase-change material.

33. The manufacturing method according to claim 32, in which the catalyst is iron or an aluminium and iron bilayer system.

34. The manufacturing method according to claim 32, further comprising compacting of carbon nanotubes by immersing the network of cells in alcohol solution, and drying the network of cells in air.

35. The manufacturing method according to claim 32, further comprising, prior to a) to d), production of one or more cavities in a support, wherein said cavity or cavities receive a network of cells, and after d) closure of the cavity or cavities by a cover.

36. The manufacturing method according to claim 35, wherein the substrate is formed by the bottom of the cavity or cavities and wherein a) to d) take place on a bottom of the cavity or cavities.

37. The manufacturing method according to claim 36, further comprising deposition of a layer of ductile thermal conductive material on the bottom of the cavity or cavities intended to be pointing towards an interior of the cavity.

38. The manufacturing method according to claim 37, wherein the substrate is formed by the cover, and wherein a) to d) take place on the cover.

39. The manufacturing method according to claim 38, further comprising deposition of a layer of ductile thermal conductive material on a cover face intended to be pointing towards an interior of the cavity.
